(19) United States
(12) Patent Application Publication
(10) Pub. No.: US 2015/0214926 A1
(43) Pub. Date: Jul. 30, 2015

(54) DISCRETE-TIME FILTER

(71) Applicant: HUAWEI TECHNOLOGIES CO., LTD., Shenzhen (CN)

(72) Inventors: Massoud TOHIDIAN, Delft (NL); Iman MADADI, Delft (NL); Robert Bogdan STASZEWSKI, Delft (NL)

(21) Appl. No.: 14/577,542

(22) Filed: Dec. 19, 2014

Related U.S. Application Data
(63) Continuation of application No. PCT/EP2012/062027, filed on Jun. 21, 2012.

(51) Int. Cl. H03H 7/00

(52) U.S. Cl. CPC H03H 11/04

(57) ABSTRACT

A discrete-time filter for filtering an input signal comprises a switched capacitor network, the switched capacitor network comprising an input and an output, a number of switched capacitor paths arranged in parallel between the input and the output, each switched capacitor path comprising a capacitor, and a switch circuitry for switching each capacitor at a different time instant for outputting a filtered input signal.

### CROSS-REFERENCE TO RELATED APPLICATIONS

This application is a continuation of International Patent Application No. PCT/EP2012/062027, filed on Jun. 21, 2012, which is hereby incorporated by reference in its entirety.

### BACKGROUND

The present invention relates to a discrete-time filter for filtering an input signal.

Receivers are electronic circuits that receive RF signal at high frequency and down-convert it to baseband for further processing and demodulation. They usually amplify the weak desired RF signal and filter undesired adjacent signals and blockers around. A receiver is commonly tunable by changing the LO frequency of its local oscillator to receive a specific channel in a certain band.

Multi-band receivers are able to receive a signal from two or more different bands located at different frequencies. Since these bands might be located far from each other, a multi-band receiver should be tunable or programmable to cover all desired bands.

A multi-standard receiver can receive signals in different standards. One of the main differences between these standards is signal bandwidth. Therefore bandwidth of a multi-standard receiver must be selectable to cover different standards. However, other requirements of receiver such as receive frequency, sensitivity, linearity, filtering requirement, etc. might be different in different standards. Rather than including multiple different receivers for different bands or standards, a single multi-band/multi-standard receiver might be used with programmable receive frequency and input bandwidth.

The conventional superheterodyne receiver architecture 1500 as illustrated in FIG. 15 provides high quality filtering at intermediate frequency (IF), Flicker free gain at IF but applies fixed intermediate frequency. A received radio frequency signal with frequency f_{RF}=f_{LO}+f_{IF} in the superheterodyne receiver architecture 1500 passes a pre-select stage 1501, a low noise amplifier 1503, an RF mixer 1505, an intermediate frequency (IF) filter 1507, an IF amplifier 1509, an IF mixer 1511, a channel selector 1513, a baseband gain stage 1515 and analog-to-digital converter 1517 before it is passed to the digital modem 1519 for further processing.

However, due to quadrature operation of mixers 1605 multiplying the desired band of frequency ω₁ with the local oscillator (LO) frequency ω_{LO} as depicted in the frequency diagram 1600 of FIG. 16, images 1603 of the desired band 1601 are aliased at intermediate frequency IF resulting in undesired aliasing components 1609 in IF band of frequency ω_{IF}. A low pass filter 1607 is used for image rejection.

Receivers should support multi-band multi-standard operation to cover a wide range of communication standards. On the other hand, to be cost effective it is desired to highly integrate it as a single chip preferably in a nano-scale CMOS process. Homodyne architecture (including ZIF and LIF) is a common receiver structure due to its well-recognized capability of monolithic integration. FIG. 17 illustrates a common homodyne receiver architecture 1700. A received radio frequency signal with frequency f_{RF}=f_{LO} in the Homodyne receiver architecture 1700 passes a pre-select stage 1701, a low noise amplifier 1703, a mixer 1705, a channel selector 1707, a baseband gain stage 1709 and an analog-to-digital converter 1711 before it is passed to the digital modem 1713 for further processing.

However, the homodyne receiver architecture suffers from several technical problems which require special attention to make this architecture suitable for different communication standards. Different interference phenomena are illustrated in FIG. 18 depicting a homodyne receiver with a low noise amplifier 1801, a mixer 1803, a low pass filter 1805, a gain stage 1407 and an analog-to-digital converter 1809.

DC offset is a common problem in ZIF (zero intermediate frequency) structure caused by self-mixing of the local oscillator (LO) signal cos ω_{LO}t amplified or not amplified through the LNA amplifier 1801 or strong interferer at the down-converting mixer 1803 as illustrated in FIG. 18. It would be worse if LO leakage reaches to the antenna. In this case it will cause time-varying DC offset dependent on the ever-varying antenna environment. So, normally DC offset cancellation techniques need to be used for ZIF (zero intermediate frequency). Since LO frequency is substantially the same as input RF frequency, the LO leakage can be higher than in case of a receiver with different LO frequency. In some cases, LO leakage calibration is needed. Also, second-order intermodulation (IM2) is a common problem in ZIF, which usually needs IP2 calibration. In ZIF structure normally small part of receiver gain is provided at RF stage and the major part is provided at BB stages. Therefore, flicker noise of baseband (BB) amplifier increases the total noise floor (NF) of the system. Designers usually try to minimize it by using large transistor sizes in BB. Moreover, since the first filtering is performed in BB and considering the RF gain before BB, the first BB filter has to be highly linear. Operational amplifier (Opamp)-based or Gm-C based biquad filter is a well-known block for this purpose but it consumes high power.

Superheterodyne architecture as depicted in FIG. 19 has been recognized to solve the above problems. A received radio frequency signal with frequency f_{RF}=f_{LO}+f_{IF} in the superheterodyne receiver architecture 1900 passes a pre-select stage 1905, a low noise amplifier 1907, an RF mixer 1909, an external (off-chip) intermediate frequency (IF) filter 1903, an IF amplifier 1911, an IF mixer 1913, a channel selector 1915, a baseband gain stage 1917 and an analog-to-digital converter 1919 before it is passed to the digital modem 1921 for further processing.

However the conventional superheterodyne architecture 1900 as depicted in FIG. 19 introduces its own set of problems. IF filter 1903, are conventionally implemented as off-chip components which are costly. Then high power for I/O buffers is needed to drive the off-chip filter 1903. Further, the off-chip filter 1903 is only accessible through bond wires which provide parasitic inductance and capacitance. In addition, the receiver with a fixed frequency IF filter requires two independent local oscillators, one to down-convert from RF to IF and another one to down-convert from IF to BB.

### SUMMARY

The invention provides an efficient concept for on-chip discrete-filter implementation.

In order to describe the invention in detail, the following terms, abbreviations and notations will be used:

RF: radio frequency,
IF: intermediate frequency,
ZIF: zero intermediate frequency,
LIF: low intermediate frequency,
LO: local oscillator,
BB: baseband,
BW: bandwidth,
LPF: low-pass filter,
BPF: band-pass filter.

According to a first aspect, the invention relates to a discrete-time filter for filtering an input signal, the discrete-time filter comprising a switched capacitor network, the switched capacitor network comprising an input and an output, a number of switched capacitor paths arranged in parallel between the input and the output, each switched capacitor path comprising a capacitor, and a switch circuitry for switching each capacitor at a different time instant for outputting a filtered input signal.

The discrete-time filter can thus be efficiently implemented on a single chip, thus saving space and power.

In a first possible implementation form of the discrete-time filter according to the first aspect, the switch circuitry is configured to switch each capacitor beginning with a different phase of a common clock signal.

The common clock signal can be provided by a local oscillator. The discrete-time filter is thus suitable for use within integrated circuits, where accurately specified resistors and capacitors are not economical to construct.

In a second possible implementation form of the discrete-time filter according to the first aspect as such or according to the first implementation form of the first aspect, the switch circuitry is configured to sequentially switch the capacitors across the parallel switched capacitor paths.

By sequentially switching the capacitors charge sharing between the capacitors can be achieved which can result in power efficiency of the design.

In a third possible implementation form of the discrete-time filter according to the first aspect as such or according to any of the preceding implementation forms of the first aspect, the switch circuitry is configured to periodically switch the capacitors.

Switching may be controlled by a clock signal thereby providing an efficient switching control.

In a fourth possible implementation form of the discrete-time filter according to the first aspect as such or according to any of the preceding implementation forms of the first aspect, the periodic switching is completed within a period of an input sample.

The period of the input sample can be determined by a duration of an input sample which can correspond to a period of a clock signal. The clock signal can be provided by a local oscillator. Moreover, the input sample can be efficiently partitioned to the different switching paths resulting in performance gains.

In a fifth possible implementation form of the discrete-time filter according to the first aspect as such or according to any of the preceding implementation forms of the first aspect, the switch circuitry comprises the number of input switches for switching each capacitor to the input for charging the capacitors.

The input switches provide an efficient mechanism to control charging the capacitors.

In a sixth possible implementation form of the discrete-time filter according to the first aspect as such or according to any of the preceding implementation forms of the first aspect, the switch circuitry comprises the number of output switches for switching each capacitor to the output for sequentially outputting the number of filtered sub-signals collectively representing the filtered input signal.

The output switches provide an efficient mechanism to control charging the capacitors.

In a seventh possible implementation form of the discrete-time filter according to the sixth implementation form of the first aspect, the switch circuitry comprises the number of discharge switches, each reset switch being arranged to switch one capacitor to a reference potential for discharging.

The discharge switches provide an efficient mechanism to control charge switching, in particular resetting a capacitor.

In an eighth possible implementation form of the discrete-time filter according to the sixth or the seventh implementation form of the first aspect, the discrete-time filter comprises a converting amplifier having an amplifier output coupled to the input, the converting amplifier being arranged to convert a voltage signal at an amplifier input of the converting amplifier into a current signal, the current signal forming the input signal.

Voltage-to-current conversion can be efficiently realized by the converting amplifier providing an improved dynamic range of the discrete-time filter.

In a ninth possible implementation form of the discrete-time filter according to the first aspect as such or according to any of the preceding implementation forms of the first aspect, the converting amplifier is a gm stage.

Thus, by using a gm stage the converting amplifier can be integrated in a chip.

In a tenth possible implementation form of the discrete-time filter according to the first aspect as such or according to any of the preceding implementation forms of the first aspect, the discrete-time filter comprises an input capacitor coupled to the input.

The input capacitor can be efficiently realized for storing the input signal.

In an eleventh possible implementation form of the discrete-time filter according to the first aspect as such or according to any of the preceding implementation forms of the first aspect, the discrete-time filter comprises an output capacitor coupled to the output.

The output capacitor can be efficiently realized for storing the output signal.

In a twelfth possible implementation form of the discrete-time filter according to the first aspect as such or according to any of the preceding implementation forms of the first aspect, the number is equal to or greater than 4.

When using a number greater or equal than 4, a sufficient oversampling rate with respect to a frequency of a local oscillator can be realized.

In a thirteenth possible implementation form of the discrete-time filter according to the first aspect as such or according to any of the preceding implementation forms of the first aspect, the switch circuitry forms a sampling mixer being configured to sample the input signal with a predetermined sampling rate to obtain the number of discrete-time signals sampled at different time instants in the number of switched capacitor paths.

The number of sampled discrete time signals can collectively represent an oversampled signal. Moreover, the sampling mixer makes the discrete-time filter insensitive to 2^{nd}-order nonlinearities.

In a fourteenth possible implementation form of the discrete-time filter according to the first aspect as such or according to any of the preceding implementation forms of the first aspect, the discrete-time filter is a low-pass filter or a band-pass filter or a channel selector.

The discrete-filter may operate in the baseband as well as in intermediate frequency range.

According to a second aspect, the invention relates to a method for discrete-time filtering an input signal using a switched capacitor network, the switched capacitor network comprising an input and an output, a number of parallel switched capacitor paths arranged between the input and the output, each switched capacitor path comprising a capacitor, the method comprising switching each capacitor a different time instant for filtering the input signal to output a filtered input signal.

The method can provide advantages regarding tradeoff between noise figure and distortion characteristics.

### BRIEF DESCRIPTION OF THE DRAWINGS

FIG. 1 shows a block diagram of a discrete-time filter;

FIG. 2A, 2B show a block diagram of a discrete-time filter;

FIG. 3 shows a block diagram of a discrete-time filter;

FIG. 4 shows a block diagram of a radio frequency receiver;

FIG. 5 shows a block diagram of a radio frequency receiver;

FIG. 6 shows a block diagram of a radio frequency receiver;

FIG. 7 shows a block diagram of a radio frequency receiver;

FIG. 8 shows switching signals;

FIG. 9 shows a block diagram of a discrete-time filter;

FIG. 10 shows a discrete-time filter;

FIG. 11 shows a performance diagram;

FIG. 12 shows a performance diagram;

FIG. 13 shows a block diagram of a superheterodyne receiver;

FIG. 14 shows a block diagram of a superheterodyne receiver;

FIG. 15 shows a block diagram of a conventional superheterodyne receiver architecture;

FIG. 16 shows a frequency diagram of a received signal in a conventional superheterodyne receiver architecture;

FIG. 17 shows a block diagram of a conventional homodyne receiver architecture;

FIG. 18 shows a frequency diagram of a received signal in a conventional homodyne receiver architecture; and

FIG. 19 shows a block diagram of a conventional superheterodyne receiver architecture with off-chip IF filtering.

### DETAILED DESCRIPTION

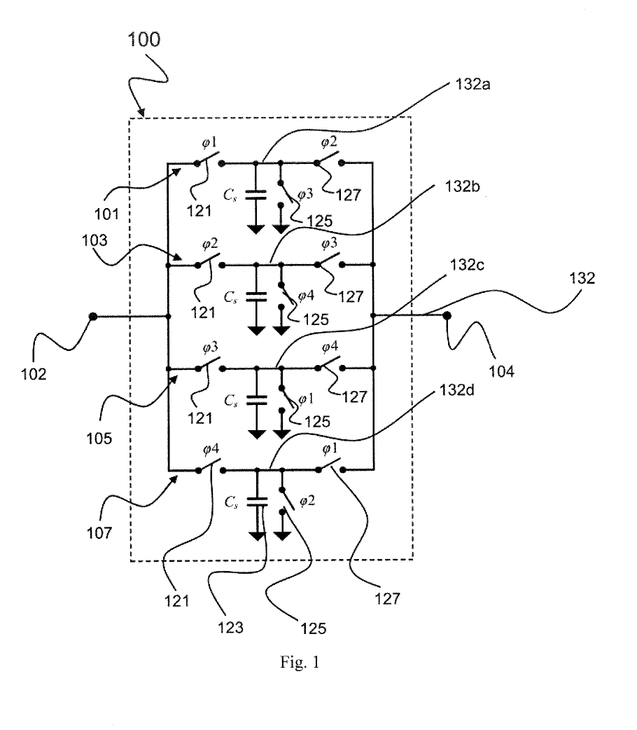

FIG. 1 shows a block diagram of a discrete-time filter 100 of a processing circuit of a radio frequency receiver according to an operational form. The discrete-time filter 100 comprises a first switched capacitor path 101, a second switched capacitor path 103, a third switched capacitor path 105 and a fourth switched capacitor path 107, which are coupled in parallel between an input 102 and an output 104 of the discrete-time filter 100. Each of the filter paths 101, 103, 105 and 107 comprises a first switch 121 serially coupled into the filter path, an input of the first switch 121 coupled to an input of the discrete-time filter 100, a capacitor 123, Cs, shunting an output of the first switch 121 to ground, a second switch 125 coupled with its input to an output of the first switch 121 and with its output to ground and a third switch 127 coupled between an input of the second switch 125 and an output of the discrete-time filter 100. The switches 121, 125 and 127 form a switch circuitry for switching each capacitor at a different time instant for outputting a filtered input signal.

The sampling rate at the input 102 can be described as fₛ₋ᵢₙ=1/Iₛ with sampling interval Tₛ and the sampling rate at each of the sub-paths 101, 103, 105 and 107 can be described as f_{s-sub}=(1/Tₛ)/4, i.e. a decimation by 4 can be used. However, since the sub-path outputs are combined in a time-staggered manner, the original data rate is restored. The discrete-time filter 100 could be a single-ended version of a differential or pseudo-differential structure.

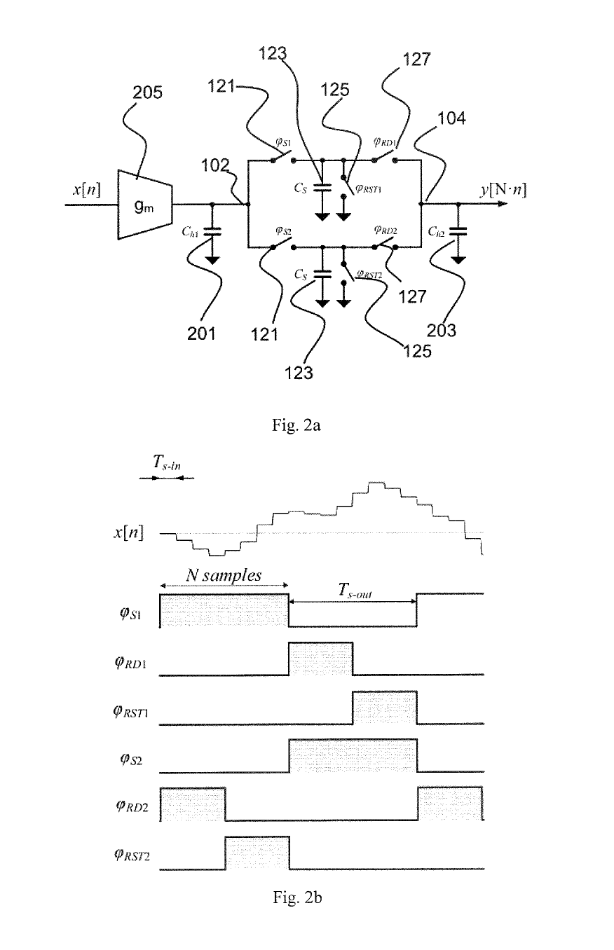

The operation of the discrete-time filter with exemplary two switched capacitor paths is depicted in FIGS. 2A and 2B.

The discrete-time filter shown in FIG. 2A additionally comprises a first history capacitor 201 coupled to the input 102, and a second history capacitor 203 coupled to the output 104. The discrete-time filter further comprises a gm stage 205 coupled to the input 102. The gm stage 205 receives e.g. a discrete-time signal x[n] exemplarily shown in FIG. 2B, wherein a filtered signal y[N*n] is outputted at the output 104. FIG. 2B shows exemplary state diagrams of the switches 121, 125 and 127 with the switch signals φS1, φRD1, φRST1, φS2, φRD2, φRST2.

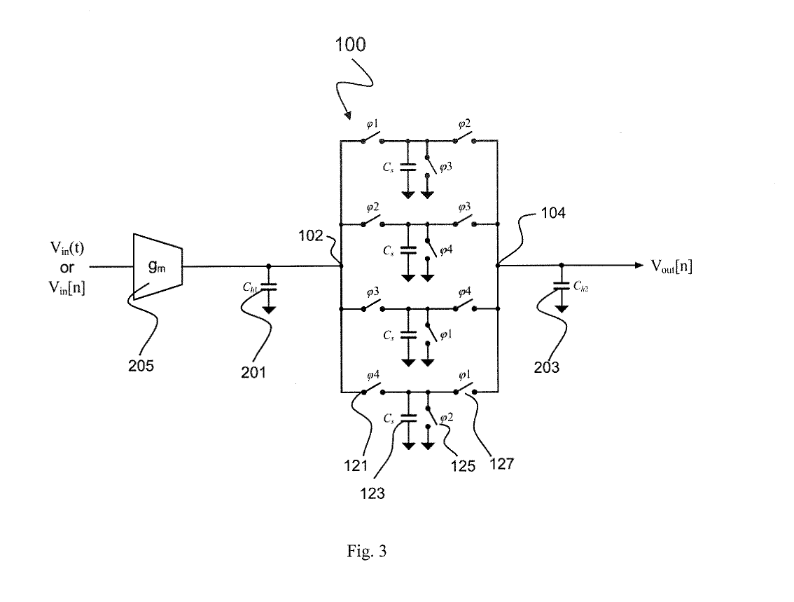

FIG. 3 shows the discrete-time filter shown in FIG. 1. In addition, history capacitors 201, 203 and the gm stage 205 as described with respect to FIG. 2 are provided. As depicted in FIG. 3, the input signal to the gm stage 205, which can convert voltage signals into current signals, may be an analogue or a digital signal. If the input signal is analogue, then the switches 121 may perform sampling, e.g. oversampling. With four switched capacitor paths, oversampling with the oversampling factor 4 may be performed. However, each switched capacitor path may operate with the frequency of the input signal.

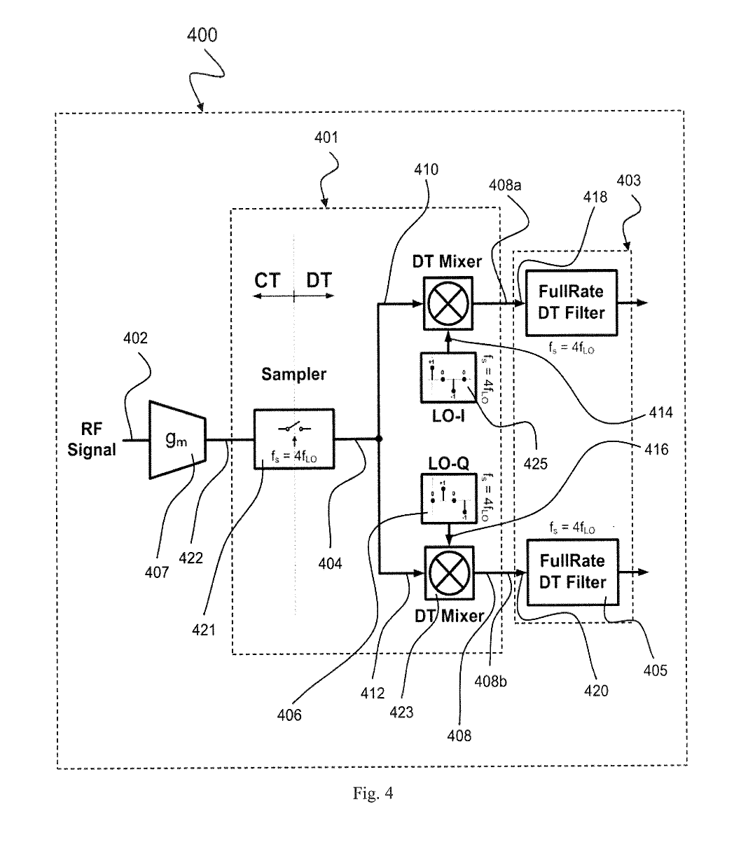

FIG. 4 shows a block diagram of a radio frequency receiver 400 according to an operational form. The radio frequency receiver 400 is configured for receiving an analogue radio-frequency signal 402. The radio frequency receiver 400 comprises a sampling mixer 401, a discrete-time filer 403 and an analogue amplifier 407.

The sampling mixer 401 is configured to sample the analogue radio frequency signal 402 using a predetermined sampling rate fₛ to obtain a discrete-time sampled signal 404, and to shift the discrete-time sampled signal 404 towards an intermediate frequency 406 to obtain an intermediate discrete-time signal 408 sampled at the predetermined sampling rate fₛ. The processing circuit 403 is configured for discrete-time processing the intermediate discrete-time signal 408 at the predetermined sampling rate fₛ.

The analogue amplifier 407 is configured to receive and amplify the analogue radio-frequency signal 402 providing an amplified analogue radio-frequency signal 422. The sampling mixer 401 is coupled to the analogue amplifier 407 and is configured to receive the amplified analogue radio-frequency signal 422 from the analogue amplifier 407. In an operational form, the analogue amplifier 407 comprises a gₘ stage as described above.

The sampling mixer 401 is a quadrature mixer comprising an in-phase path 410 and a quadrature path 412. The sampling mixer 401 comprises a sampler 421 and a quadrature discrete-time mixer 423. The sampler 421 is configured to sample the amplified analogue radio-frequency signal 422 providing the discrete-time sampled signal 404. An inphase part of the quadrature discrete-time mixer 423 is configured to mix the discrete-time sampled signal 404 with an in-phase oscillator signal 414 generated by a local oscillator 425. A quadrature part of the quadrature discrete-time mixer 423 is configured to mix the discrete-time sampled signal 404 with a quadrature oscillator signal 416 generated by the local oscillator 425. The quadrature discrete-time mixer 423 provides two discrete-time sampled sub-signals 408a, 108b representing the discrete-time sampled signal 408 at an output of the sampling mixer 401. In an operational form, the sampling mixer 401 is a direct-sampling mixer. In an operational form, the sampling mixer 401 is configured to oversample the analogue radio frequency signal 402 with an oversampling rate and to provide a number of discrete-time sampled sub-signals 408a, 408b collectively representing the discrete-time sampled signal 408, each discrete-time sampled sub-signal 408a, 408b representing the analogue radio-frequency signal 402 sampled with a sampling rate corresponding to a frequency of the analogue radio-frequency signal 402.

In an operational form, the sampler 421 is a current sampler for sampling current. The sampler 421 can be represented by a continuous-time (CT) sinc filter with a first notch at 1/Ti with sampling time Ti and anti-aliasing for image frequencies. The sampling frequency may correspond to the input-output rate. In discrete-time (DT) signal processing input charge qᵢₙ[n] is considered as the input sampled signal and output voltage Vₒᵤₜ[n] is considered as the output sampled signal according to the following equations:

$${q}_{in} [ n ] = {\int }_{{nT}_{s}}^{{nT}_{s} + {T}_{i}} {i}_{in} ( t ) d t$$

$${V}_{out} [ n ] = \frac{{q}_{in} [ n ]}{{C}_{s}}$$

In an operational form, the predetermined sampling rate fs is an oversampling rate with an oversampling factor which is 4, i.e. the predetermined sampling rate fₛ corresponds to four times the frequency of the local oscillator fₛ=4 f_{LO}.

In an operational form, the in-phase path 410 is configured to generate an in-phase oscillator signal 414 with the repeating function [1 0 −1 0]. In an operational form, the quadrature-phase path 412 is configured to generate a quadrature phase oscillator signal 416 with the repeating function [0 1 0−1]. In an operational form, the in-phase path 410 is configured to generate an in-phase oscillator signal 414 with the repeating function [1 1+√2 1+√2 1 −1 −1−√2 −1√2 −1]. In an operational form, the quadrature-phase path 112 is configured to generate a quadrature phase oscillator signal 416 with the repeating function [−1−√2 −1 1 1+√2 1+√2 1 −1 −√2].

In an operational form, the discrete-time filer 403 comprises an in-phase path 418 coupled to the in-phase path 410 of the sampling mixer 401 and a quadrature path 420 coupled to the quadrature path 412 of the sampling mixer 401.

In an operational form, the discrete-time filer 403 forms a channel selector, e.g. a switch which can be a transistor.

In an operational form, the discrete-time filer 403 comprises two a discrete-time filters 405 configured to filter the intermediate discrete-time signal 408 at the predetermined sampling rate fs in the an in-phase path and in the quadrature path. The discrete-time filter 405 is a low-pass filter or band-pass filter, in particular a complex band-pass filter. In an operational form, the discrete-time filer 403 is configured to perform a charge sharing between an in-phase and a quadrature component of the intermediate discrete-time signal 408. In an operational form, the discrete-time filer 403 comprises a switched capacitor circuit. In an operational form, the intermediate frequency is zero within a zero frequency region. The discrete-time filter 403 may be implemented as one of the discrete-time filters as shown in FIG. 1, FIG. 2 or FIG. 3 or as described above.

In an operational form, the sampling mixer 401 can be considered as a quad DT mixer operating at quadruple (4×) rate. The quadruple (4×) sampling concept is for keeping the original sample rate in the subsequent stage, thereby avoiding early decimation. In an operational form further IIR filter are added before decimation.

In an operational form, the radio frequency receiver 400 is integrated on a single chip without using external filters.

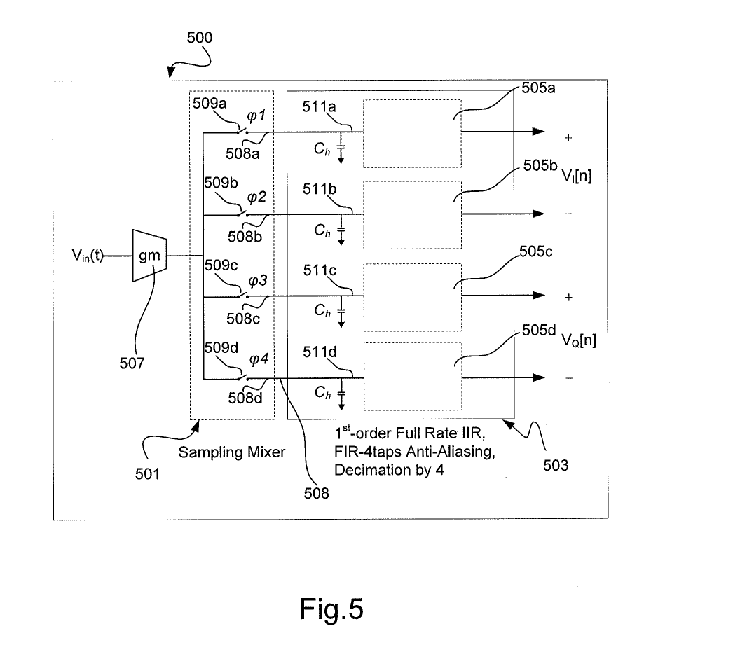

FIG. 5 shows a block diagram of a radio frequency receiver 500 according to an operational form. The radio frequency receiver 500 is configured for receiving an analogue radio-frequency signal Vin(t). The radio frequency receiver 500 comprises a sampling mixer 501, a discrete-time filer 503 and an analogue amplifier 507.

The sampling mixer 501 is configured to sample the analogue radio frequency signal Vin(t) using a predetermined sampling rate fₛ to obtain a discrete-time sampled signal, and to shift the discrete-time sampled signal towards an intermediate frequency to obtain an intermediate discrete-time signal 208 sampled at the predetermined sampling rate fₛ. The discrete-time filer 503 is configured for discrete-time filtering the intermediate discrete-time signal 508 at the predetermined sampling rate fₛ.

The analogue amplifier 507 is configured to receive and amplify the analogue radio-frequency signal Vin(t) corresponding to the analogue amplifier 507 described with respect to FIG. 1. The sampling mixer 501 is coupled to the analogue amplifier 507 and is configured to receive the amplified analogue radio-frequency signal from the analogue amplifier 507.

The sampling mixer 501 is a quadruple mixer, also called quad mixer or 4×-mixer comprising a first path 508a, a second path 508b, a third path 508c and a fourth path 508d. The sampling mixer 501 comprises a first switch 509a for controlling the first path 508a by a first control signal φ1, a second switch 509b for controlling the second path 508b by a second control signal φ2, a third switch 509c for controlling the third path 508c by a third control signal φ3 and a fourth switch 509d for controlling the fourth path 508d by a fourth control signal φ4. A representation of the control signals φ1, φ2, φ3 and φ4 is described above.

The discrete-time filter 503 comprises a first path 511 a coupled to the first path 508a of the sampling mixer 501, a second path 511b coupled to the second path 508b of the sampling mixer 501, a third path 511c coupled to the third path 508c of the sampling mixer 501 and a fourth path 511d coupled to the fourth path 508d of the sampling mixer 501. Each of the paths 511a, 511b, 511c and 511d of the discrete-time filer 503 comprises a capacitor Cₕ shunted to ground and a respective filter 505a, 505b, 505c, 505d serially coupled into the respective path 508a, 508b, 508c and 508d of the discrete-time filer 503.

In an operational form, each of the respective paths 508a, 508b, 408c and 508d of the discrete-time filer 503 forms a first order full rate IIR low-pass filter. In an operational form, each of the respective paths 508a, 508b, 508c and 508d of the discrete-time filer 503 provides the transfer function described by:

$$H ( z ) = \frac{{V}_{out} ( z )}{{q}_{in} ( z )} = \frac{\frac{1}{{C}_{h} + {C}_{s}}}{1 - \frac{{C}_{h}}{{C}_{h} + {C}_{s}} {z}^{- 1}}$$

The discrete-time filer 503 forms according to an operational form a first order full rate IIR filter or FIR with 4 taps for anti-aliasing with optional decimation by 4.

In an operational form, the discrete-time filter 503 is implemented as one of the discrete-time filters as shown in FIG. 1, FIG. 2 or FIG. 3 or as described above.

The sampling mixer 501 can correspond to the sampling mixer 401 as described with respect to FIG. 4. The discrete-time filter 503 may correspond to the discrete-time filter 403 as described with respect to FIG. 4. The analog amplifier 507 may correspond to the analog amplifier 507 as described with respect to FIG. 4.

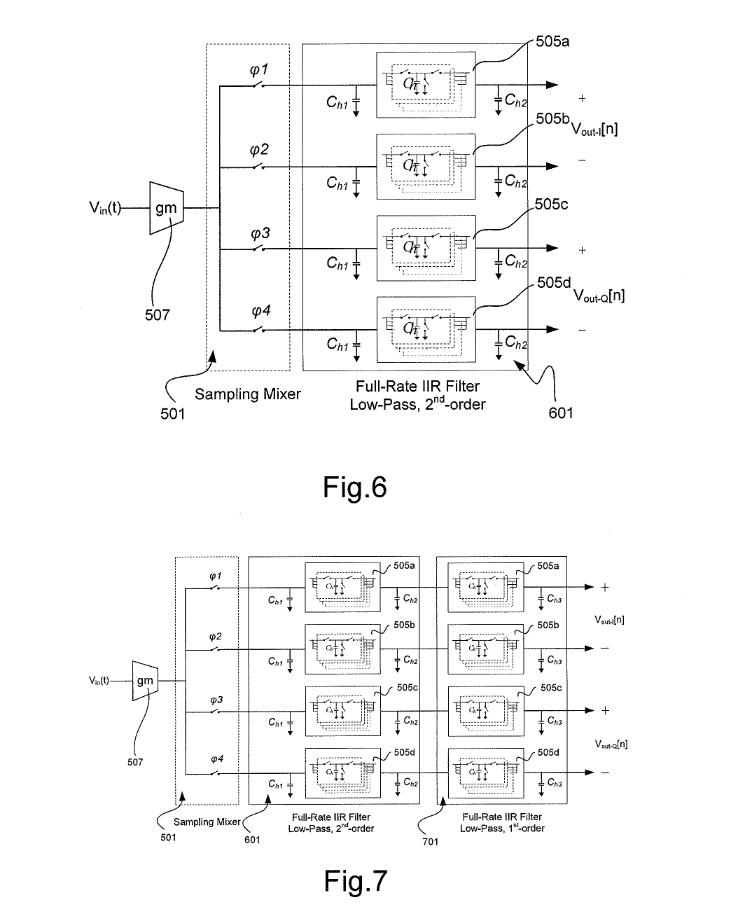

FIG. 6 shows a block diagram of a radio frequency receiver according to an operational form. In difference to the radio frequency receiver shown in FIG. 5, the radio frequency receiver shown in FIG. 6 comprises capacitors Cₕ₂ coupled to an output of each discrete-time filter 505a, 505b, 505c, 505d, thus forming a composite discrete-time filter 601, e.g. a 2^{nd}-order IIR Filter, e.g. low pass filter. The discrete-time filter 403 as described with respect to FIG. 4 and the discrete-time filter 503 as described with respect to FIG. 5 may comprise a composite discrete-time filter 601.

The 2^{nd}-order transfer function for each path is as follows:

$$H ( z ) = \frac{{V}_{out} ( z )}{{q}_{in} ( z )} = \frac{\frac{1}{{C}_{h 1} + {C}_{s}}}{1 - \frac{{C}_{h 1}}{{C}_{h 1} + {C}_{s}} {z}^{- 1}} \times \frac{\frac{{C}_{s}}{{C}_{h 2} + {C}_{s}}}{1 - \frac{{C}_{h 2}}{{C}_{h 2} + {C}_{s}} {z}^{- 1}}$$

FIG. 7 shows a block diagram of a radio frequency receiver according to an operational form. In difference to the radio frequency receiver shown in FIG. 6, the radio frequency receiver shown in FIG. 7 comprises a further composite discrete-time filter 701 arranged downwards the composite discrete-time filter 601. More specifically, outputs of the discrete-time filters 505a, 505b, 505c, 505d of the composite discrete-time filter 601 are respectively serially coupled (in a cascaded manner) to inputs of discrete-time filters 505a, 505b, 505c, 505d of the composite discrete-time filter 601. The outputs of the discrete-time filters 505a, 505b, 505c, 505d are respectively terminated with capacitors Cₕ₃. The composite discrete-time filter 701 forms according to an operational form a first order IIR low pass filter.

The discrete-time filter 403 as described with respect to FIG. 4 and the discrete-time filter 503 as described with respect to FIG. 5 can comprise a further composite discrete-time filter 701.

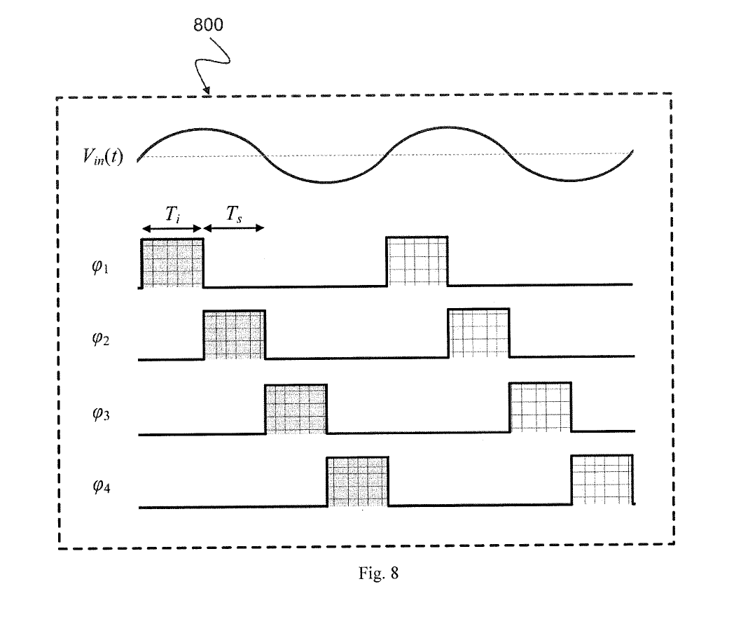

FIG. 8 shows a graph 800 with a set of switching signals for controlling the switches of a discrete-time filter according to any operational form shown above. A first switching signal φ1 is a pulsed signal with pulse time Ti and sample time Ts. A second switching signal φ2 is a pulsed signal with pulse time Ti and sample time Ts. A third switching signal φ3 is a pulsed signal with pulse time Ti and sample time Ts. A fourth switching signal φ4 is a pulsed signal with pulse time Ti and sample time Ts. In this implementation, the sample time Ts corresponds to the pulse time Ti. The pulses of the four switching signals are time shifted with respect to each other's pulse time Ti. When the first switching signal φ1 falls from high signal level to low signal level, i.e. the pulse is ending, the second switching signal φ2 rises from low signal level to high signal level, i.e. the pulse is starting. The same condition holds for the relation between the second φ2 and the third φ3 pulse signal, the third φ3 and the fourth φ4 pulse signal and the fourth φ4 and the first φ1 pulse signal.

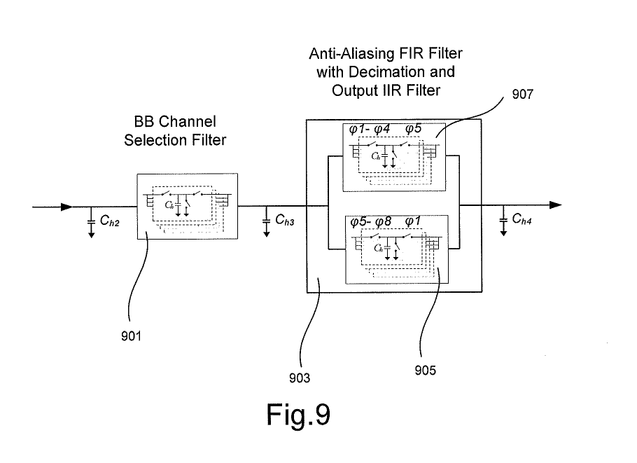

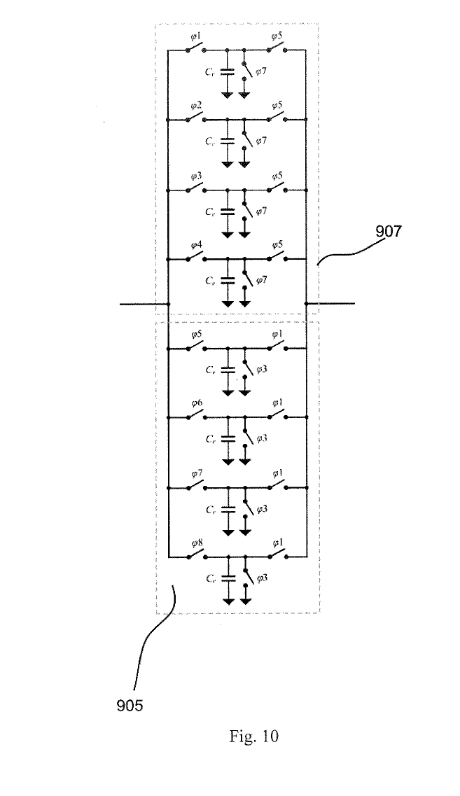

FIG. 9 shows a block diagram of a discrete-time filter according to an operational form which is composed of a serial connection (in a cascaded manner) of a first discrete-time filter 901 and a second discrete-time filter 903. The first discrete-time filter 901 may be implemented as shown e.g. in FIG. 1. The second discrete-time filter 903 comprises a parallel arrangement of two-discrete time filters 905 and 907, each of which having according to an operational form shown in FIG. 10 a structure as shown in FIG. 1. In addition, at the input and the output of the first discrete-time filter 901 capacities Ch2 and Ch3 arranged. An output of the second discrete-time filter 903 is terminated via capacitor Ch4.

The first discrete-time filter 901 may form a baseband (BB) selection filter, whereas the second discrete-time filter 903 may form an antialiasing FIR filter e.g. 4 taps and decimation and output IIR filter. Thereby, a biquad narrow-band discrete-time filter may be implemented.

The discrete-time filter 403 as described with respect to FIG. 4 and the discrete-time filter 503 as described with respect to FIG. 5 may comprise the features of first discrete-time filter 901 and/or the second discrete-time filter 903.

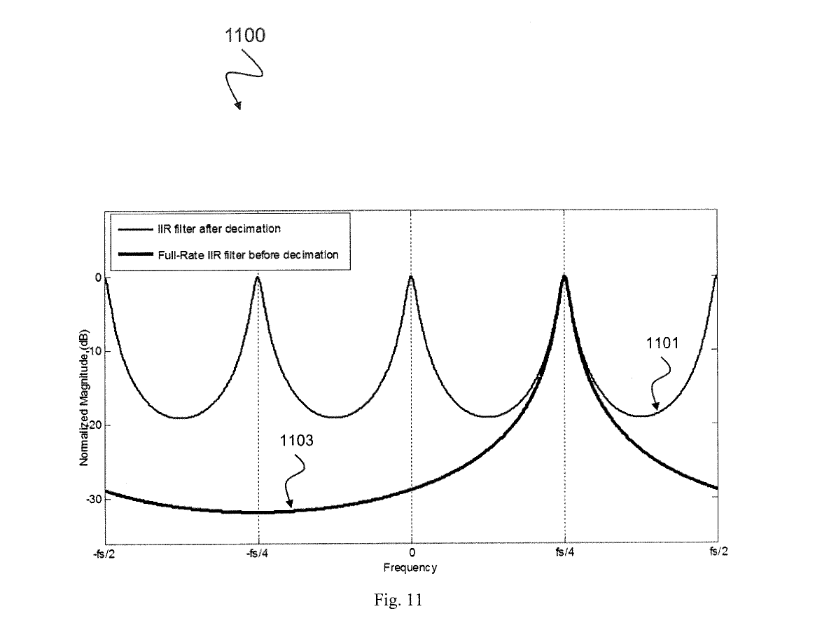

FIG. 11 shows a performance diagram 1100 of a radio frequency receiver according to an operational form, wherein discrete-time filtering according to the principles described herein is performed. The diagram 1100 depicts an IIR filter output signal 1101 of a conventional RF receiver where IIR filtering is performed after decimation, i.e. the IIR filter output signal 1101 carries images resulting from decimation. The diagram 1100 further depicts an IIR filter output signal 1103 of a radio frequency receiver according to aspects of the invention where IIR filtering is performed prior to decimation. The performance of the IIR filter output signal 1103 of a radio frequency receiver according to aspects of the invention with respect to the IIR filter output signal 1101 of a conventional RF receiver is increased by a factor of about 30 dB at and around the alias frequencies 0, −fs/4 and −fs/2.

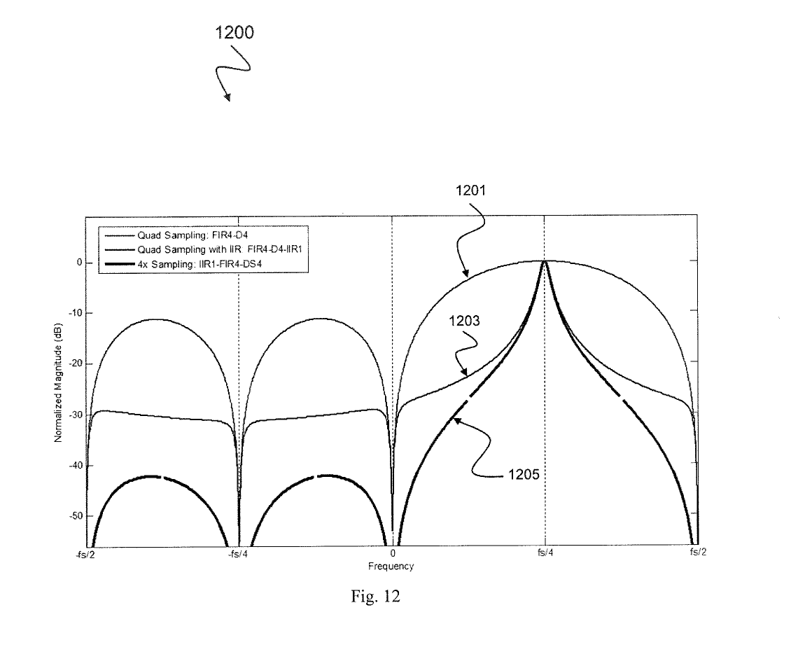

FIG. 12 shows a performance diagram 1200 of a radio frequency receiver according to an operational form, wherein discrete-time filtering according to the principles described herein is performed. The diagram 1200 depicts a first output signal 1201 of a conventional RF receiver applying FIR filtering and down-sampling. The diagram 1200 depicts a second output signal 1201 of a conventional RF receiver applying FIR filtering, down-sampling and IIR filtering, wherein the IIR filtering is after the down-sampling. The diagram 1200 depicts a third output signal 705 of a radio frequency receiver according to aspects of the invention applying FIR filtering, IIR filtering and down-sampling, wherein the down-sampling is after the FIR filtering and after the IIR filtering. The performance of the third output signal 1205 of a radio frequency receiver according to aspects of the invention is increased with respect to the first output signal 1201 of a conventional RF receiver by a factor of at least 30 dB and with respect to the second output signal 1203 of a conventional RF receiver by a factor of at least 10 to 15 dB at and around the alias frequencies 0, −fs/4 and −fs/2 with respect to the down-sampling. The notches of the third output signal 1205 show a wider bandwidth than the notches of the first and second output signals 1201 and 1203.

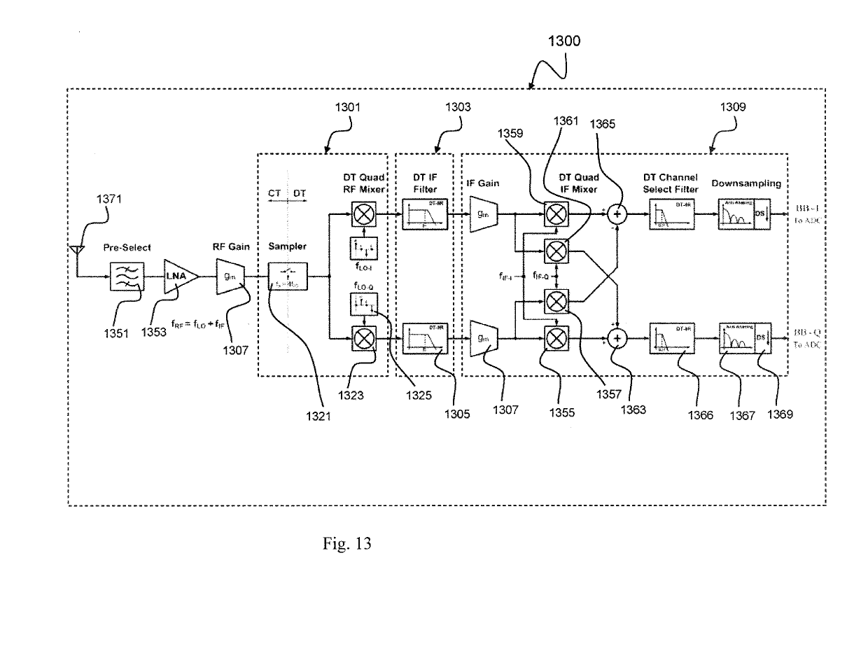

FIG. 13 shows a block diagram of a superheterodyne receiver 1300 according to an operational form, wherein all discrete-time filters can be implemented according to the principles described herein.

The superheterodyne receiver 1300 is configured for receiving an analogue radio-frequency signal received from an antenna 1371. The superheterodyne receiver 1300 comprises a sampling mixer 1301 which may correspond to the sampling mixer described above, a discrete-time filter 1303 which may correspond to the discrete-time filter with respect to FIG. 1 and a discrete-time mixer 1309 which may correspond to the discrete-time mixer described above. The superheterodyne receiver 1300 comprises a pre-select gain stage 1351, a low-noise amplifier (LNA) 1353 and an RF gain stage 1307 which may be an analogue amplifier.

The analogue radio-frequency signal received from antenna 1371 passes the pre-select gain stage 1351, the low-noise amplifier (LNA) 1353, the RF gain stage 1307, the sampling mixer 1301, the discrete-time filter 1303 and the discrete-time mixer 1309 before it is provided to an analog-digital converter.

The sampling mixer 1301 is configured to sample the output signal received from the RF gain stage 1307 using a predetermined sampling rate fₛ in a sampler 1321 to obtain a discrete-time sampled signal, and to shift the discrete-time sampled signal towards a first intermediate frequency f_{LO} in a quadrature mixer 1323 to obtain an intermediate discrete-time signal sampled at the predetermined sampling rate fₛ. The quadrature mixer 1323 comprises an in-phase path providing an in-phase component and a quadrature path providing a quadrature component of the processed intermediate discrete-time signal.

The discrete-time filter 1303 comprises a DT IF filter 1305 configured for discrete-time processing the intermediate discrete-time signal at the predetermined sampling rate fₛ to obtain a filtered signal having in-phase and quadrature component. The discrete-time mixer 1309 is configured to shift the filtered signal towards a second intermediate frequency f_{IF}.

The discrete-time mixer 1309 comprises an IF gain stage 1307 and a DT quad IF mixer comprising a first mixer component 1355, a second mixer component 1357, a third mixer component 1359, fourth mixer component 1361, a first adder 1363 and a second adder 1365. The discrete-time mixer 1309 further comprises a DT channel select filter 1366, an anti-aliasing filter 1367 and a down-sampler 1369. In the DT quad IF mixer, the in-phase path at an input of the DT quad IF mixer is coupled via the fourth mixer component 1361 to the first adder 1363 and coupled via the third mixer component 1359 to the second adder 1365; the quadrature path at an input of the DT quad IF mixer is coupled via the first mixer component 1355 to the first adder 1363 and coupled via the second mixer component 1357 to the second adder 1365. An output of the first adder 1363 forms the quadrature path at an output of the DT quad IF mixer and an output of the second adder 1365 forms the in-phase path at an output of the DT quad IF mixer. The in-phase and quadrature paths at the output of the DT quad IF mixer are coupled to the DT channel select filter 1366, the anti-aliasing filter 1367 and the down-sampler 1369.

The RF input signal is sampled at RF stage and all subsequent operations are done in discrete-time domain (DT). Hence the block diagram is divided into two portions: continuous-time (CT) and discrete-time (DT). At first LNTA 1353 amplifies the received RF voltage signal and converts it into current signal. This amplification reduces input referred noise of the subsequent stages and hence improving the total noise floor (NF) of the receiver. Then, the RF signal is oversampled in the sampler 1321 with about two times higher than Nyquist rate. This ensures that the RF signal remains at the same frequency after sampling with no down-conversion or frequency translation taking place. In addition the sampling image frequency is very far away from the wanted RF signal. Also, keeping this high sampling rate in succeeding filtering stages at IF leads to a more powerful filtering. The exact value of sampling rate (fₛ) is chosen in a way to have a straightforward DT LO signal for the RF mixer 1323, i.e. [1 0 −1 0].

The superheterodyne receiver 1300 solves the problem that superheterodyne architectures generally suffer from the IF image frequency by applying quadrature structure. This would be prohibitive in a conventional superheterodyne receiver. Because it needs two separate paths for quadrature (I and Q) signals, so it doubles all hardware including costly off-chip IF filter and their buffers. However in a fully-integrated structure of the superheterodyne receiver 1300 as depicted in FIG. 13 this is not an issue.

DT quadrature RF mixer 1323, 1325 down-converts the sampled signal to IF using quadrature DT LO signals and keeps the output sampling rate the same as the sampling rate of the input. In an operational form, IF in this architecture is LPF, BPF or a complex BPF. This filter 1323, 1325 operates at least at the same original sample rate of the input without introducing extra image frequencies. In an operational form using a LPF, its corner frequency is slightly higher than IF frequency, e.g. f_{IF}+BW/2. In an operational form using BPF, its center frequency is located at f_{IF}. Also, in the operational form using a complex BPF, its center frequency is placed either at +f_{IF} or −f_{IF} depending on quadrature mixer operation. In the operational form, a full-rate LPF is used. In an operational form, several cascaded IF filter are used in this architecture to improve its filtering function. Also, the IF gain can be distributed between these IF filters. The hip IF frequency can be easily selected to be higher than the flicker noise corner frequency to avoid NF degradation.

The DT quadrature IF mixer 1355, 1357, 1359, 1361, 1363, 1365 down-converts the IF signal to base-band (BB) with negative or positive image frequency rejection. In an operational form having only one local oscillator (LO) for the whole receiver, f_{IF} is an integer division of f_{w}.

A chain of IIR filters 1366, FIR anti-aliasing filters 1367, decimations 1369 and gain stages prepare the signal for ADC. IIR filters 1366 select one or some adjacent channels and filter out the rest. The high sampling rate after IF mixer is gradually reduced by some decimations 269, each protected by an FIR anti-aliasing filter 1367. Gain stages provide enough gain so that signal level dynamic range matches ADC's dynamic range.

In an operational form, LNTA 1353 is implemented as a unified LNTA or a common LNA followed by a gₘ stage 1307.

Sample rate at RF can be calculated from RF and IF frequencies:

$$\{ \begin{matrix}{f}_{RF} = {f}_{LO} \pm {f}_{IF} \\ {f}_{IF} = {f}_{LO} / N\end{matrix} ⇒ {f}_{LO} = \frac{N}{N \pm 1} {f}_{RF} .$$

The simplest DT quadrature LO signal is LOhd 1=[1 0 −1 0] and LO_{Q}=[0 1 0 −1]. Hence input sampling rate is chosen here to be:

fₛ=4×f_{w}.

In an operational form, RF sampler 1321 and DT quadrature RF mixer 1323, 1325 are implemented at the same time in one block 1301 using switches. By providing quadrature LO signals for two Gilbert cells, for example, in order to perform window integration sampling, the RF input signal is sampled and down-converted to IF frequency. At the output of this stage, the samples are stored on sampling capacitors.

In an operational form, DT IF mixer 1355, 1357, 1359, 1361, 1363, 1365 in this structure is implemented by some simple switches or by 3^{rd} order image rejection mixer or by even more advanced structures. In an operational form, simple switches are used. In an operational form, quadrature IF LO signals of the IF mixer are IF₁=[1 0 −1 0] and IF_{Q}=[0 1 0 −1]. However, its sample rate is reduced by N. The integration of N samples at IF into the sampling capacitor after IF mixer forms a temporal uniform-weighted N-tap FIR filter, which attenuates alias frequencies more before folding down on the wanted signal. Alias frequencies have been attenuated prior to it by the IF BPF filter.

Right after the IF mixer 1355, 1357, 1359, 1361, 1363, 1365, an IIR filter 1366 limits bandwidth (BW) to the desired channels. In BB signal processing, decimation can be done in temporal, e.g. by integrating some samples changing the clock rate or spatial, e.g. by adding different samples on different samplers together. In the superheterodyne receiver 1300 depicted in FIG. 13, a temporal decimation is used in the BB.

The superheterodyne receiver 1300 uses sufficient filtering so that linearity requirement of the subsequent blocks is relaxed. Thus, in an operational form, the rest of gain is provided by low power simple gₘ stage instead of using high linearity opamp and feedback structure.

In an operational form, the superheterodyne receiver 1300 is a DT superheterodyne receiver with digital backend. In this operational form, the RF Gain is mainly for converting voltage to current. The sampler can be part of DT mixer or subsequent filter. The DT Quad RF Mixer is used for down-converting signal to IF frequency in DT domain. The DT IF Filter is used for suppressing image frequencies of IF mixer. By using IF gain Flicker-free amplification of the signal is provided. The DT Quad IF Mixer is for down-converting the signal to baseband. The DT Channel Select Filter is used as narrow-band IIR filter to select desired channel. The down-sampling is performed by decimation with anti-aliasing filter to meet ADC sampling rate.

The sampling mixer 1301 can correspond to the sampling mixer 401 as described with respect to FIG. 4. The discrete-time filter 1303 may correspond to the discrete-time filter 403 as described with respect to FIG. 4. The analog amplifiers 1307 may correspond to the analog amplifier 407 as described with respect to FIG. 4.

In the following, considerations are shown for choosing the appropriate IF frequency:

Higher IF (e.g. f_{LO}/8)
Image frequencies are far from wanted channel
   the first dominant at f_{RF}±4f_{IF} distance
   Preselect filter and tuned LNA improves image rejection significantly
Image rejection of the receiver itself would be worse: −50 dB at f_{RF}±2f_{IF}
Faster switches and gₘ with higher BW is required at IF stage

Lower IF (e.g. f_{LO}/16)
Better image rejection but more close to the RF signal: −60 dB at f_{RF}±2f_{IF}
Flicker noise corner should be considered at this lower IF

Dynamic IF
In busy environment with high level blockers, IF freq can be switched so that improve image rejection for that specific blocker signal
   e.g. f_{RF}=1.0625 GHz, f_{LO}=1.0 GHz, f_{IF}=f_{LO}/16=62.5 MHz→f_{img}=812.5 MHz
      f_{RF}=1.0625 GHz, f_{LO}=944.4 MHz, f_{IF}=f_{LO}/8=118 MHz→f_{img}=590.3 MHz

In an operational form, the superheterodyne receiver 1300 implements a method with the following steps:

Converting RF signal to current (1^{st} gₘ stage)

Down-conversion of RF signal to IF frequency (RF Mixer)

Filtering out important image frequencies of the 2^{nd} mixer (IF Filter)

2^{nd} gₘ: more gain and conversion into current

Down-conversion to Base-Band

Base-Band Channel Selection Filtering

Alias-Protected Decimation for reducing sample rate

Therefore, the superheterodyne receiver 1300 has the following advantages:

Getting rid of LO feed-through
LO frequency is different than receiving RF signal,

Flicker-free gain,

No external IF filter,

Fully discrete-time operation
Precise control of filters corner frequencies by capacitor ratio and clock frequency,

Scalability: Scaling with Moore's Law.

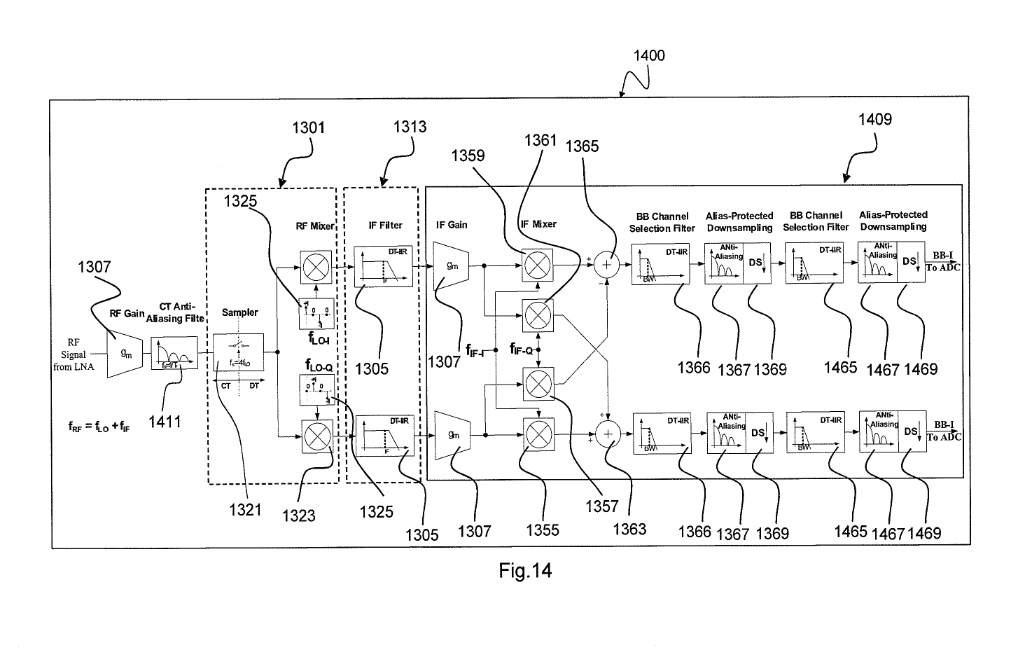

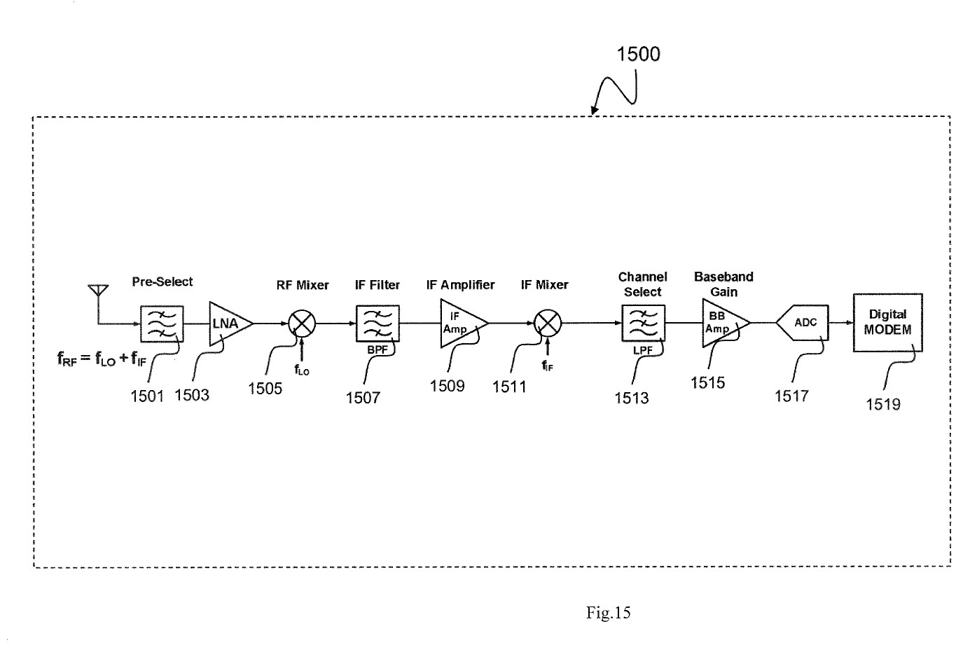

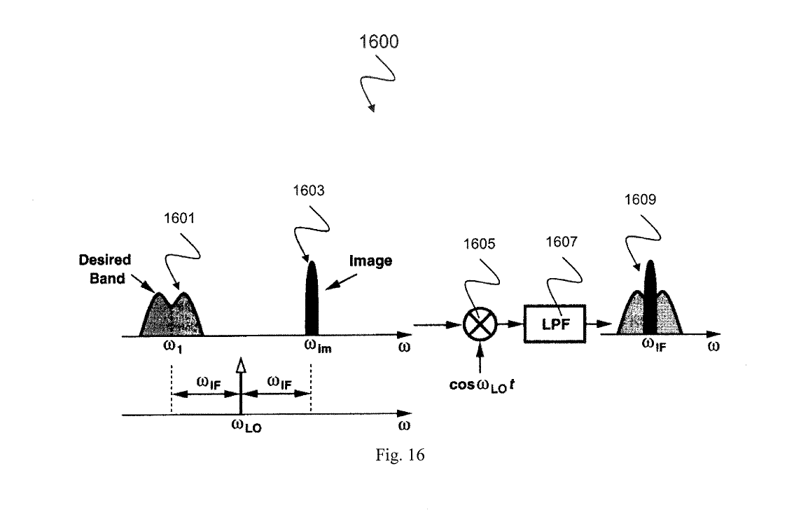

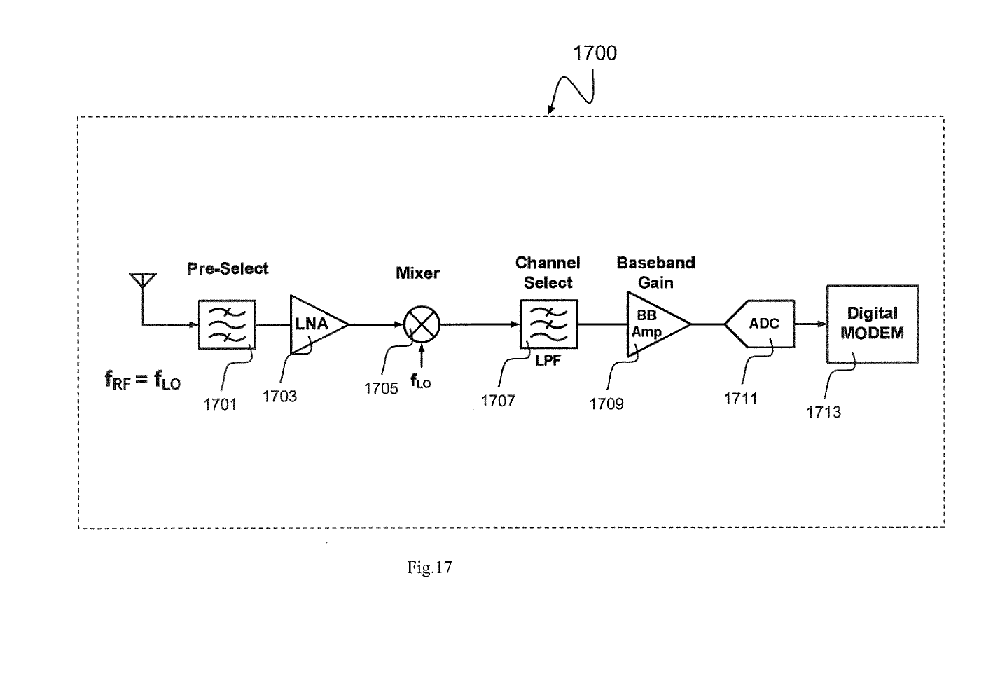

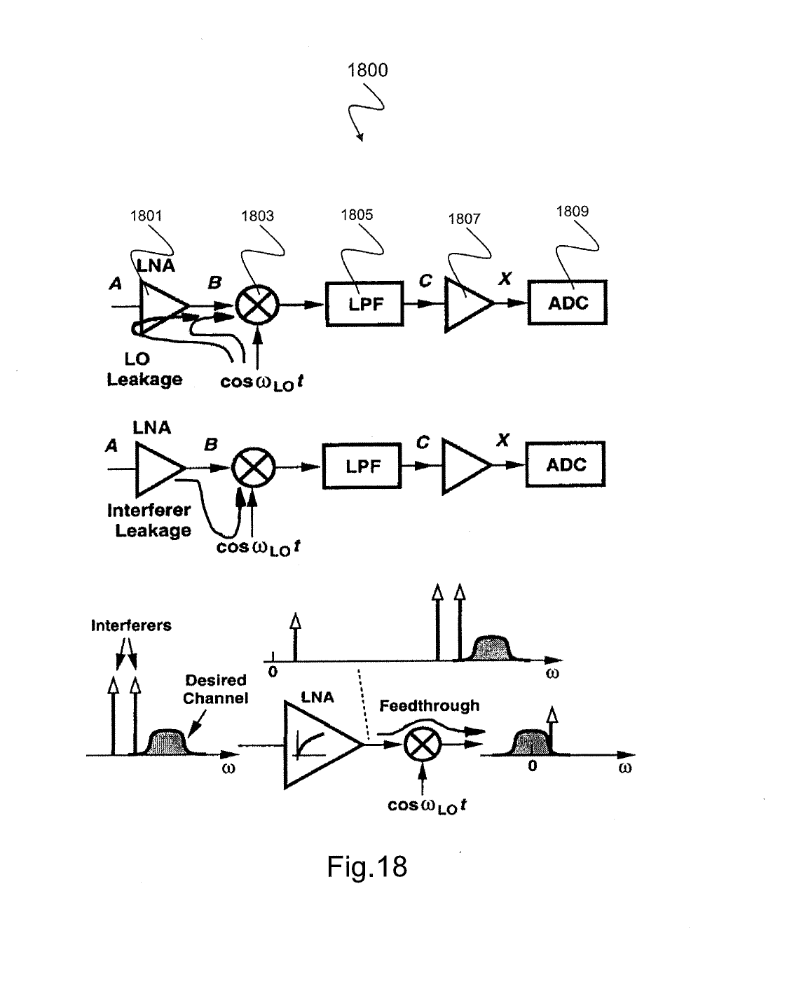

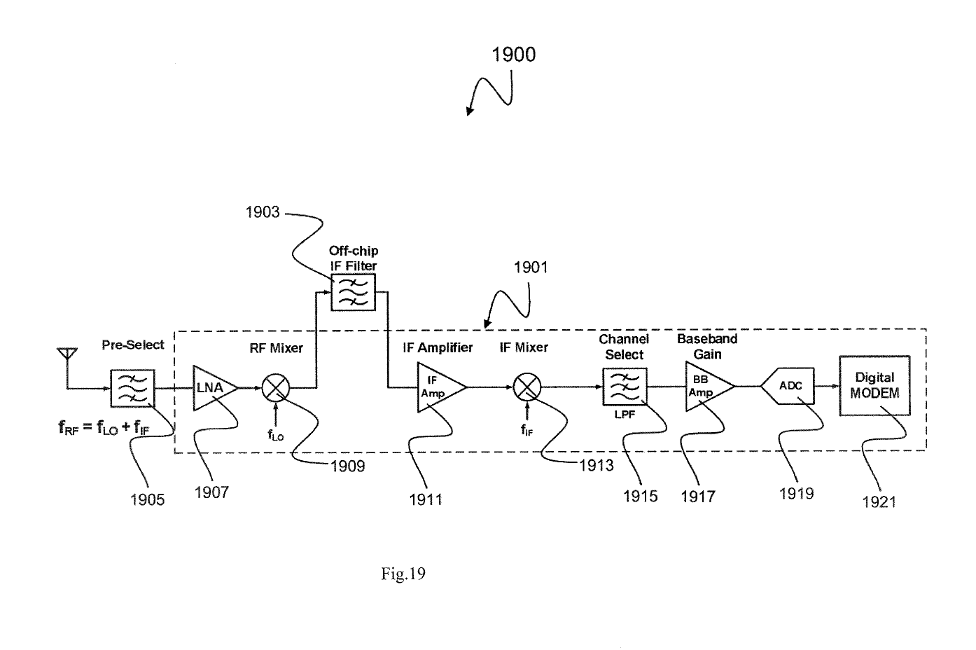

FIG. 14 shows a block diagram of a superheterodyne receiver 1400 according to an operational form, wherein all discrete-time filters can be implemented according to the principles described herein. The structure of the superheterodyne receiver 1400 corresponds to the structure of the superheterodyne receiver 1300 described with respect to FIG. 13 but the superheterodyne receiver 1400 comprises an anti-aliasing filter 1411 coupled between the RF gain stage 1307 and the sampler 1321. The discrete-time mixer 1309 corresponds to the discrete-time mixer 1309 described with respect to FIG. 13 but comprises in downstream direction an additional filtering stage comprising a BB channel selection filter 1465, an alias-protection filter 1467 and a down-sampler 1469.

The additional filtering stage is configured to adapt to the requirements of different ADC specifications, for example GSM, e.g. with 14-bit, 100 kHz noise shaped AE-ADC sampling at 9-MS/s or with 14-bit, 500 kHz oversample ADC (1 bit quantizer), 450-MS/s; LTE, e.g. with 11-bit, 40 MS/s Nyquist ADC and WCDMA, e.g. with 9-bit, 8 MS/s Nyquist ADC.

The sampling mixer 1301 may correspond to the sampling mixer 401 as described with respect to FIG. 4. The discrete-time filter 1313 may correspond to the discrete-time filter 403 as described with respect to FIG. 4. The analog amplifiers 1307 may correspond to the analog amplifier 407 as described with respect to FIG. 4.

What is claimed is:

1. A discrete-time filter for filtering an input signal, the discrete-time filter comprising:
a switched capacitor network, the switched capacitor network comprising:
an input and an output;
a plurality of switched capacitor paths arranged in parallel between the input and the output, each switched capacitor path comprising a capacitor; and
switch circuitry for switching each capacitor at a different time instant for outputting a filtered input signal.

2. The discrete-time filter of claim 1, wherein the switch circuitry is configured to connect each capacitor to the input beginning with a different phase of a common clock signal.

3. The discrete-time filter of claim 1, wherein the switch circuitry is configured to sequentially connect each capacitor to the input according to a defined sequence.

4. The discrete-time filter of claim 1, wherein the switch circuitry is configured to periodically connect each capacitor to the input.

5. The discrete-time filter of claim 4, wherein the periodic switching is completed within a period of an input signal.

6. The discrete-time filter of claim 1, wherein the switch circuitry comprises input switches for connecting each capacitor to the input for charging the capacitor.

7. The discrete-time filter of claim 1, wherein the switch circuitry comprises output switches for connecting each capacitor to the output for sequentially outputting filtered sub-signals collectively representing the filtered input signal.

8. The discrete-time filter of claim 1, wherein the switch circuitry comprises discharge switches, each discharge switch being configured to connect one capacitor to a reference potential for discharging.

9. The discrete-time filter of claim 1, further comprising:
a converting amplifier having an amplifier output coupled to the input, the converting amplifier being configured to convert a voltage signal at an amplifier input of the converting amplifier into a current signal, the current signal forming the input signal.

10. The discrete-time filter of claim 9, wherein the converting amplifier forms a gm stage.

11. The discrete-time filter of claim 1, comprising an input capacitor coupled to the input.

12. The discrete-time filter of claim 1, comprising an output capacitor coupled to the output.

13. The discrete-time filter of claim 1, wherein the plurality of switched capacitor paths comprises at least four switched capacitor paths.

14. The discrete-time filter of claim 1, wherein the switch circuitry forms a sampling mixer configured to sample the input signal at a predetermined sampling rate to obtain discrete-time signals sampled at different time instants corresponding to the plurality of switched capacitor paths.

15. The discrete-time filter of claim 1, wherein the discrete-time filter is a low-pass filter or a band-pass filter or a channel selector.

16. A method for discrete-time filtering an input signal using a switched capacitor network, the switched capacitor network comprising, an input and an output, a plurality of paths arranged between the input and the output, each path comprising a capacitor, the method comprising:
switching each capacitor at a different time instant for filtering the input signal to output a filtered input signal.
